(19) United States
(12) Patent Application Publication
(10) Pub. No.: US 2019/0206901 A1
(43) Pub. Date: Jul. 4, 2019

(54) DISPLAY PANEL AND MANUFACTURING PROCESS THEREOF

(71) Applicants: HKC Corporation Limited, Shenzhen (CN); Chongqing HKC Optoelectronics Technology Co., Ltd., Chongqing (CN)

(72) Inventor: YU-JEN CHEN, Chongqing (CN)

(21) Appl. No.: 16/325,740

(22) PCT Filed: May 5, 2017
(86) PCT No.: PCT/CN2017/083213

§ 371 Date: Feb. 15, 2019

(30) Foreign Application Priority Data
Dec. 30, 2016 (CN) 201611259751.0

(51) Int. Cl. H01L 27/12; H01L 29/45; H01L 29/49

(52) U.S. Cl. CPC H01L 27/124; H01L 29/4908; H01L 29/45; H01L 27/1259

(57) ABSTRACT

The present application discloses a display panel and a manufacturing process. The display panel including: a substrate, an insulation layer disposed on the substrate, and second-layer wires disposed on the insulation layer, where a lower portion of the second-layer wires includes a first high-adhesion metal layer, an upper portion of the second-layer wires includes a second high-adhesion metal layer, a middle of the second-layer wires includes a middle conducting layer, and the second-layer wires are coupled with a source driver of the display panel.

### TECHNICAL FIELD

The present application relates to the technical field of displays, and in particular relates to a display panel and a manufacturing process thereof.

### BACKGROUND

Display apparatuses have numerous advantages, such as a thin body, power saving, no radiation, etc., and are widely used. Most display apparatuses in the current market are backlit display apparatuses, each including a display panel and a backlight module. Working principle of the display panel is that liquid crystals are put in two parallel substrates, and a driving voltage is applied to the two substrates to control a rotational direction of the liquid crystals, to refract light rays of the backlight module to generate a picture.

Thin film transistor liquid crystal display apparatuses (TFT-LCD) currently maintain a leading status in the display field because of low power consumption, excellent picture quality, high production yield, and other properties. Similarly, the TFT-LCD includes a display panel and a backlight module. The display panel includes a color filter substrate (CF substrate), a thin film transistor substrate (TFT substrate) and transparent electrodes on relative inner sides of the above substrates. A layer of liquid crystals (LC) is positioned between two substrates. The display panel changes a polarized state of light by controlling the direction of the LCs through an electric field, for penetration and obstruction of a light path via a polarized plate to display.

With the gradual development of the TFT-LCD apparatuses in the aspects of oversize, high driving frequency, high resolution and the like, a high-quality wire manufacturing technology dominates the market when the TFT-LCD apparatuses are manufactured. How to effectively decrease the resistance and the parasitic capacitance of a wire of the panel becomes increasingly important in order to cope with a specification of a future LCD apparatus with high frequency and high resolution, while the problems of peeling of a metal film and the like are caused due to poor adhesiveness of a wire easily caused by a metal structure of the wire in current second-layer wires manufacturing process.

### SUMMARY

The purpose of the present application is to provide a display panel which solves the problem of poor adhesiveness of second-layer wires.

Additionally, the present application also provides a manufacturing process of the display panel.

The purpose of the present application is realized by the following technical solution: A display panel, including: a substrate, an insulation layer and second-layer wires, the insulation layer is disposed on the substrate, and the second-layer wires are disposed on the insulation layer, where a lower portion of the second-layer wires includes a first high-adhesion metal layer, an upper portion of the second-layer wires includes a second high-adhesion metal layer, a middle of the second-layer wires includes a middle conducting layer, and the second-layer wires are coupled with a source driver of the display panel.

Optionally, the thickness of the middle conducting layer is greater than the thickness of the first high-adhesion metal layer and the thickness of the second high-adhesion metal layer.

The thickness of the middle conducting layer is greater than the thickness of the first high-adhesion metal layer and is also greater than the thickness of the second high-adhesion metal layer. The middle conducting layer can adopt metal with lower resistance property, and is thicker so as to effectively decrease the resistance and the parasitic capacitance of the second-layer wires of the panel. The first high-adhesion metal layer and the second high-adhesion metal layer adopt metal with better adhesion property. The middle conducting layer is connected to an upper layer and a lower layer by the first high-adhesion metal layer and the second high-adhesion metal layer, so that the adhesiveness is better and the middle conducting layer is difficult to be peeled from the upper layer and the lower layer. The first high-adhesion metal layer and the second high-adhesion metal layer are mainly used for adhering the upper layer and the lower layer, so that the thickness is small, and the cost may be saved.

Optionally, the width of a bottom of the middle conducting layer is greater than that the width of the top of the middle conducting layer, the width of the first high-adhesion metal layer is the same as the width of the bottom of the middle conducting layer, and the width of the second high-adhesion metal layer is the same as the width of the top of the middle conducting layer.

The width of the bottom of the middle conducting layer is greater than the width of the top of the middle conducting layer, so that manufacturing is convenient, molding is stable, and yield is high. The width of the first high-adhesion metal layer is the same as the width of the bottom of the middle conducting layer, and the width of the second high-adhesion metal layer is the same as the width of the top of the middle conducting layer, so that manufacturing is convenient. Contact area between the middle conducting layer and the first high-adhesion metal layer and contact area between the middle conducting layer and the second high-adhesion metal layer are largest, so that an adhesion is better. The middle conducting layer is preferably a trapezoid, in particular to an isosceles trapezoid.

Optionally, the middle conducting layer is made of copper, aluminum, silver, gold, chromium, or molybdenum or an alloy of the above metal, and the first high-adhesion metal layer and the second high-adhesion metal layer are both made of molybdenum or a molybdenum alloy.

The copper, the aluminum, the silver, the gold, the chromium, the molybdenum or the alloy of the above metal have better conductivity and lower resistance property, so as to meet the need of the display panel. The molybdenum or the molybdenum alloy can realize better adhesiveness. On one hand, the molybdenum or the molybdenum alloy can be better adhered with the metal of the middle conducting layer, and on the other hand, the molybdenum or the molybdenum alloy can be better adhered and fixed with other layers of the display panel, such as a filter layer, the insulation layer, a passivation layer (a PV layer) and the like, and the molybdenum or the molybdenum alloy is convenient in material selection and mature in a manufacturing technology. Additional raw materials are not needed, so that cost of the raw materials and storage cost are reduced. New materials do not need to be added in a material list, so as to facilitate process management and purchase. The second high-adhesion metal layer can be disposed by a set of devices shared with the first high-adhesion metal layer without additional devices, and subsequent etching does not need additional devices and materials.

The second-layer wires include a source wire segment disposed on a thin film transistor (TFT), and the second high-adhesion metal layer is only disposed on the source wire segment of the second-layer wires.

The source wire segment of the TFT adopts the second-layer wires with a three-layer structure, and the other second-layer wires adopt a wire with a two-layer structure, thereby decreasing the thickness of the display panel.

Optionally, the second-layer wires include a drain wire segment disposed on the TFT and the second high-adhesion metal layer is disposed on the drain wire segment of the second-layer wires.

The drain wire segment of the TFT also adopts the second-layer wires with a three-layer structure, and the drain wire segment can also obtain good adhesiveness.

Optionally, the display panel also includes a first-layer wires positioned between the substrate and the insulation layer, the first-layer wires are integrally covered with a third high-adhesion metal layer and a fourth high-adhesion metal layer, the first-layer wires include a gate wire segment disposed on the TFT, a semiconductor layer corresponding to a gate is disposed on the insulation layer, the source wire segment and the drain wire segment of the TFT, which are spaced from each other, are disposed on two ends of the semiconductor layer, a channel is positioned between the source wire segment and the drain wire segment, and the semiconductor layer is disposed on the bottom of the channel.

The substrate is integrally covered with the first-layer wires. Either the gate wire segment of the TFT or a connecting segment between a line scanning driver and the gate of the TFT adopts a three-layer structure. Therefore, the property of the TFT is improved, the overall adhesiveness of the display panel is better, quality of the first-layer wires is improved, product yield is enhanced, and production cost is reduced.

Optionally, the second-layer wires are integrally covered with the first high-adhesion metal layer and the second high-adhesion metal layer.

The second-layer wires adopt three-layer structures. Therefore, the property of the TFT is improved, the overall adhesiveness of the display panel is better, quality of the second-layer wires is improved, product yield is enhanced, and the production cost is reduced.

According to another aspect of the present application, the present application also discloses a manufacturing process of the display panel, includes the following steps:

disposing an insulation layer on a substrate,

disposing a first high-adhesion metal layer on the insulation layer,

disposing a middle conducting layer on the first high-adhesion metal layer,

disposing a second high-adhesion metal layer on the middle conducting layer, and

etching the first high-adhesion metal layer, the middle conducting layer and the second high-adhesion metal layer to form second-layer wires.

The first high-adhesion metal layer, the middle conducting layer and the second high-adhesion metal layer of the second-layer wires are sequentially disposed on the insulation layer and then are etched together, thereby improving the quality of the second-layer wires, enhancing the product yield, reducing the production cost and enhancing the adhesiveness of the second-layer wires with the insulation layer and other layers, so that the second-layer wires are difficult to be peeled from other layers connected to the second-layer wires, where the first high-adhesion metal layer and the second high-adhesion metal layer adopt identical materials, and additional raw materials are not needed. Therefore, the cost of the raw materials and the storage cost are reduced. New materials do not need to be added in a material list, facilitating process management and purchase. The second high-adhesion metal layer may be disposed by a set of devices shared with the first high-adhesion metal layer without additional devices, and subsequent etching does not need additional devices and materials.

Optionally, the step of arranging the insulation layer on the substrate includes the following steps:

disposing a third high-adhesion metal layer on the substrate,

disposing a second middle conducting layer on the third high-adhesion metal layer,

disposing a fourth high-adhesion metal layer on the second middle conducting layer,

etching the third high-adhesion metal layer, the second middle conducting layer and the fourth high-adhesion metal layer to form first-layer wires, and

disposing the insulation layer on the first-layer wires.

The third high-adhesion metal layer, the second middle conducting layer and the fourth high-adhesion metal layer of the first-layer wires are sequentially disposed on the substrate and then are etched together, thereby improving quality of the first-layer wires, enhancing product yield, reducing production cost and enhancing the adhesiveness of the first-layer wires with the substrate and other layers, so that the first-layer wires are difficult to be peeled from other layers connected to the first-layer wires. Therefore, the overall adhesiveness of the display panel is better.

Compared with the prior art, the present application has the following technical effects that:

The second-layer wires of the display panel coupled with the source driver adopt a three-layer structure, and the first high-adhesion metal layer, the middle conducting layer and the second high-adhesion metal layer that are connected with connected to the insulation layer are sequentially arranged from bottom to top. The middle conducting layer adopts metal with lower resistance property, thereby effectively decreasing the resistance and the parasitic capacitance of the second-layer wires of the display panel. The first high-adhesion metal layer and the second high-adhesion metal layer of the second-layer wires adopt metal with better adhesion property, so that the middle conducting layer may also be well adhered and fixed with the first high-adhesion metal layer and the second high-adhesion metal layer. Meanwhile, the middle conducting layer may also be adhered and fixed with the upper layer and the lower layer by the first high-adhesion metal layer and the second high-adhesion metal layer. Therefore, the adhesiveness is better, and the middle conducting layer is difficult to be peeled from the upper layer and the lower layer, namely, the electrical property of the second-layer wires of the display panel can be well met, and the middle conducting layer can be well adhered and fixed with the upper layer and the lower layer, thereby enhancing product yield and reducing production costs.

### BRIEF DESCRIPTION OF DRAWINGS

The drawings included are used to provide further understanding of embodiments of the present application, constitute portion of the description, and are used for illustrating implementation manners of the present application, and interpreting principles of the present application together with text description. Apparently, the drawings in the following description are merely some embodiments of the present application, and for those ordinary skilled in the art, other drawings can also be obtained according to the drawings without contributing creative labor. In the drawings:

FIG. 1 is a sectional schematic diagram of second-layer wires of a display panel of an embodiment of the present application.

FIG. 2 is a partial schematic diagram of a display panel of an embodiment of the present application.

FIG. 3 is another sectional schematic diagram of second-layer wires of a display panel of an embodiment of the present application.

FIG. 4 is another partial schematic diagram of a display panel of an embodiment of the present application.

FIG. 5 is a schematic diagram of a TFT of a display panel of an embodiment of the present application.

FIG. 6 is a schematic diagram of a TFT, an upper layer and a lower layer of a display panel of an embodiment of the present application.

FIG. 7 is another schematic diagram of a TFT of a display panel of an embodiment of the present application.

FIG. 8 is a schematic diagram of second-layer wires of a display panel of an embodiment of the present application.

FIG. 9 is another schematic diagram of second-layer wires of a display panel of an embodiment of the present application.

FIG. 10 is another schematic diagram of second-layer wires of a display panel of an embodiment of the present application.

FIG. 11 is another schematic diagram of a TFT of a display panel of an embodiment of the present application.

FIG. 12 is another schematic diagram of a TFT, an upper layer and a lower layer of a display panel of an embodiment of the present application.

FIG. 13 is a schematic diagram of a manufacturing process of a display panel of an embodiment of the present application.

FIG. 14 is another schematic diagram of a manufacturing process of a display panel of an embodiment of the present application.

### DETAILED DESCRIPTION

Specific structure and function details disclosed herein are only representative and are used for the purpose of describing exemplary embodiments of the present application. However, the present application may be specifically achieved in many alternative forms and shall not be interpreted to be only limited to the embodiments described herein.

It should be understood in the description of the present application that terms such as “central”, “horizontal”, “upper”, “lower”, “left”, “right”, “vertical”, “horizontal”, “top”, “bottom”, “inner”, “outer”, etc. indicate direction or position relationships shown based on the drawings, and are only intended to facilitate the description of the present application and the simplification of the description rather than to indicate or imply that the indicated device or element must have a specific direction or constructed and operated in a specific direction, and therefore, shall not be understood as a limitation to the present application. In addition, the terms such as “first” and “second” are only used for the purpose of description, rather than being understood to indicate or imply relative importance or hint the number of indicated technical features. Thus, the feature limited by “first” and “second” can explicitly or impliedly include one or more features. In the description of the present application, the meaning of “a plurality of” is two or more unless otherwise specified. In addition, the term “comprise” and any variant are intended to cover non-exclusive inclusion.

It should be noted in the description of the present application that, unless otherwise specifically regulated and defined, terms such as “installation,” “bonded,” and “bonding” shall be understood in broad sense, and for example, may refer to fixed bonding or detachable bonding or integral bonding; may refer to mechanical bonding or electrical bonding; and may refer to direct bonding or indirect bonding through an intermediate medium or inner connection of two elements. For those of ordinary skill in the art, the meanings of the above terms in the present application may be understood according to concrete conditions.

The terms used herein are intended to merely describe concrete embodiments, not to limit the exemplary embodiments. Unless otherwise noted clearly in the context, singular forms “one” and “single” used herein are also intended to include plurals. It should also be understood that the terms “comprise” and/or “include” used herein specify the existence of stated features, integers, steps, operation, units and/or assemblies, not excluding the existence or addition of one or more other features, integers, steps, operation, units, assemblies and/or combinations of these.

The present application will be described in detail below in combination with the drawings and optional embodiments.

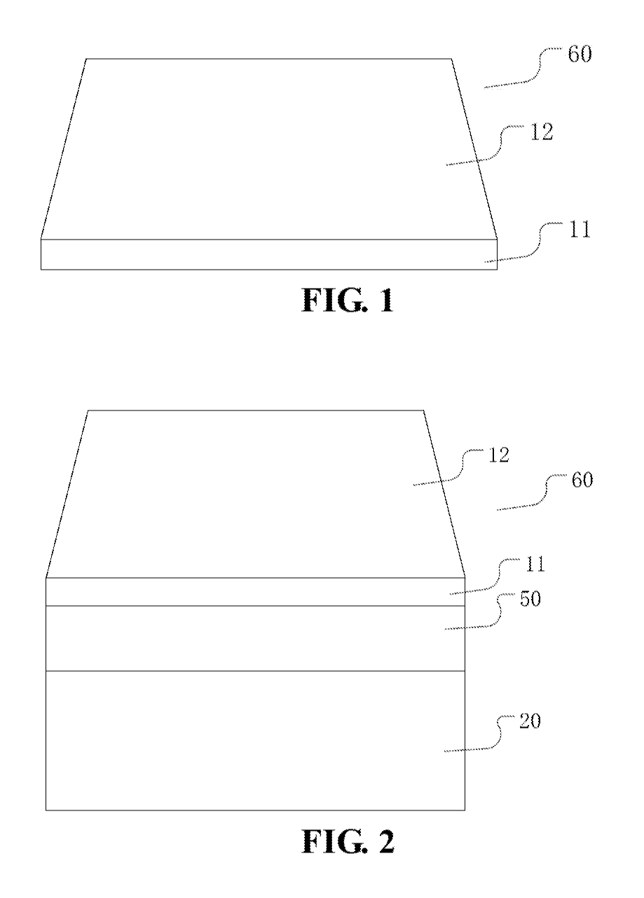

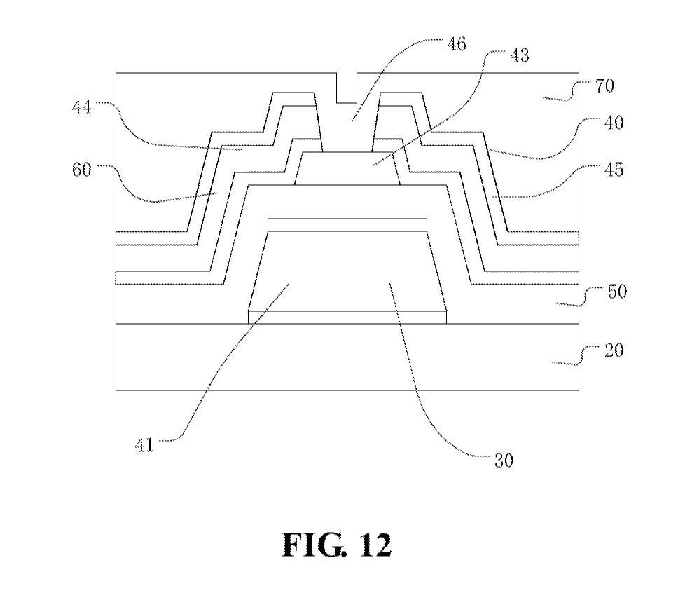

A display panel and a manufacturing process of embodiments of the present application are described below with reference to FIGS. 1-14.

As shown in FIG. 1 and FIG. 2, a display panel in embodiments of FIG. 1 and FIG. 2 includes a substrate 20, an insulation layer 50 and second-layer wires 60, where the insulation layer 50 is disposed on the substrate 20, the second-layer wires 60 are disposed on the insulation layer 50, the lower portion of the second-layer wires 60 includes an adhesive metal layer 11, the upper portion of the second-layer wires 60 includes a conducting layer 12, and the second-layer wires 60 are coupled with a source driver of the display panel.

The second-layer wires 60 of the display panel coupled with the source driver adopt a two-layer structure, and the adhesive metal layer 11 and the conducting layer 12 that are connected to the insulation layer 50 are sequentially arranged from bottom to top. The conducting layer 12 adopts metal with lower resistance property, thereby effectively decreasing the resistance and the parasitic capacitance of the second-layer wires 60 of the display panel. The adhesive metal layer 11 of the second-layer wires 60 adopts metal with better adhesion property, so that the conducting layer 12 can be well adhered and fixed with a first high-adhesion metal layer 61. Meanwhile, the conducting layer 12 may also be adhered and fixed with the insulation layer 50 by the adhesive metal layer 11. Therefore, the adhesiveness is better, so that the conducting layer 12 is difficult to be peeled from the insulation layer 50, namely, the electrical property of the second-layer wires 60 of the display panel may be well met, and the conducting layer 12 may be well adhered and fixed with the insulation layer 50, thereby enhancing product yield and reducing production cost.

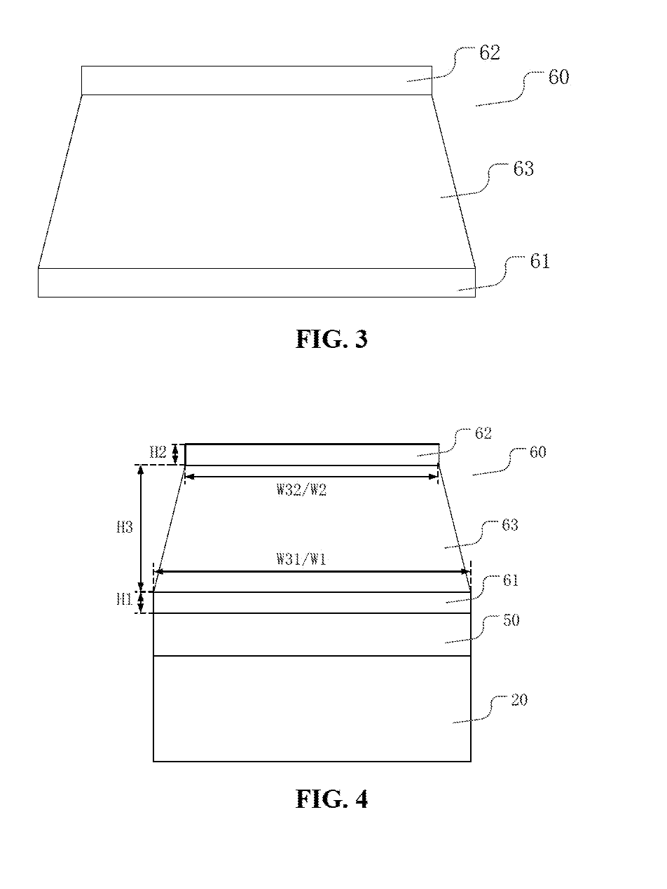

As shown in FIG. 3 and FIG. 4, a display panel in embodiments of FIG. 3 and FIG. 4 including: a substrate 20, an insulation layer 50 disposed on the substrate 20 and second-layer wires 60 disposed on the insulation layer 50, where a lower portion of the second-layer wires 60 includes a first high-adhesion metal layer 61, an upper portion of the second-layer wires 60 includes a second high-adhesion metal layer 62, the middle of the second-layer wires 60 includes a middle conducting layer 63, and the second-layer wires 60 are coupled with a source driver of the display panel.

The second-layer wires 60 of the display panel coupled with the source driver adopt a three-layer structure, and the first high-adhesion metal layer 61, the middle conducting layer 63 and the second high-adhesion metal layer 62 that are connected to the insulation layer 50 are sequentially arranged from bottom to top. The middle conducting layer 63 adopts metal with lower resistance property, thereby effectively decreasing the resistance and the parasitic capacitance of the second-layer wires 60 of the display panel. The first high-adhesion metal layer 61 and the second high-adhesion metal layer 62 of the second-layer wires 60 adopt metal with better adhesion property, so that the middle conducting layer 63 may also be well adhered and fixed with the first high-adhesion metal layer 61 and the second high-adhesion metal layer 62. Meanwhile, the middle conducting layer 63 may also be adhered and fixed with an upper layer and a lower layer by the first high-adhesion metal layer 61 and the second high-adhesion metal layer 62. Therefore, the adhesiveness is better, so that the middle conducting layer 63 is difficult to be peeled from the upper layer and the lower layer, namely, the electrical property of the second-layer wires 60 of the display panel can be well met, and the middle conducting layer 63 can be well adhered and fixed with the upper layer and the lower layer, thereby enhancing product yield and reducing production cost.

In one or more embodiments, as shown in FIG. 4, a display panel in an embodiment of FIG. 4 includes a substrate 20, an insulation layer 50 disposed on the substrate 20 and a second-layer wires 60 disposed on the insulation layer 50, where a lower portion of the second-layer wires 60 includes a first high-adhesion metal layer 61, an upper portion of the second-layer wires 60 includes a second high-adhesion metal layer 62, the middle of the second-layer wires 60 includes a middle conducting layer 63, and the second-layer wires 60 are coupled with a source driver of the display panel.

The thickness of the middle conducting layer 63 is greater than the thickness of the first high-adhesion metal layer 61 and the thickness of the second high-adhesion metal layer 62.

The thickness of the middle conducting layer 63 is greater than the thickness of the first high-adhesion metal layer 61 and is also greater than the thickness of the second high-adhesion metal layer 62. The middle conducting layer 63 may adopt metal with lower resistance property and is thicker so as to effectively decrease the resistance and the parasitic capacitance of the second-layer wires 60 of the panel. The first high-adhesion metal layer 61 and the second high-adhesion metal layer 62 adopt metal with better adhesion property. The middle conducting layer 63 is connected to an upper layer and a lower layer by the first high-adhesion metal layer 61 and the second high-adhesion metal layer 62, so that the adhesiveness is better and the middle conducting layer 63 is difficult to be peeled from the upper layer and the lower layer. The first high-adhesion metal layer 61 and the second high-adhesion metal layer 62 are mainly used to adhere the upper layer and the lower layer, so that the thickness is small, and cost may be saved. Optionally, the thickness of the middle conducting layer 63 may be greater than the sum of the thicknesses of the first high-adhesion metal layer 61 and the second high-adhesion metal layer 62.

In one or more embodiments, the width of the bottom of the middle conducting layer 63 is greater than the width of the top of the middle conducting layer 63. The width of the first high-adhesion metal layer 61 is the same as the width of the bottom of the middle conducting layer 63. The width of the second high-adhesion metal layer 62 is the same as the width of the top of the middle conducting layer 63.

The width of the bottom of the middle conducting layer 63 is greater than the width of the top of the middle conducting layer 63, so that manufacturing is convenient, molding is stable, and yield is high. The width of the first high-adhesion metal layer 61 is the same as the width of the bottom of the middle conducting layer 63, and the width of the second high-adhesion metal layer 62 is the same as the width of the top of the middle conducting layer 63, so that manufacturing is convenient. Contact area between the middle conducting layer 63 and the first high-adhesion metal layer 61 and contact area between the middle conducting layer 63 and the second high-adhesion metal layer 62 are largest, so that the adhesion is better. Optionally, the middle conducting layer 63 is a trapezoid, in particular to an isosceles trapezoid.

In one or more embodiments, the middle conducting layer 63 is made of copper, aluminum, silver, gold, chromium, molybdenum or an alloy of the above metal, and the first high-adhesion metal layer 61 and the second high-adhesion metal layer 62 are both made of molybdenum or a molybdenum alloy.

The copper, the aluminum, the silver, the gold, the chromium, the molybdenum or the alloy of the above metal have better conductivity and lower resistance property, so as to meet the need of the display panel. The molybdenum or the molybdenum alloy may realize better adhesiveness. On one hand, the molybdenum or the molybdenum alloy may be better adhered with the metal of the middle conducting layer 63, and on the other hand, the molybdenum or the molybdenum alloy may be better adhered and fixed with other layers of the display panel, such as a filter layer, the insulation layer 50, a passivation layer 70 (a PV layer) and the like, and the molybdenum or the molybdenum alloy is convenient in material selection and mature in a manufacturing technology. Additional raw materials are not needed, so that cost of the raw materials and storage cost are reduced. New materials do not need to be added in a material list, so as to facilitate process management and purchase. The second high-adhesion metal layer 62 may be disposed by a set of devices shared with the first high-adhesion metal layer 61 without additional devices, and subsequent etching does not need additional devices and materials.

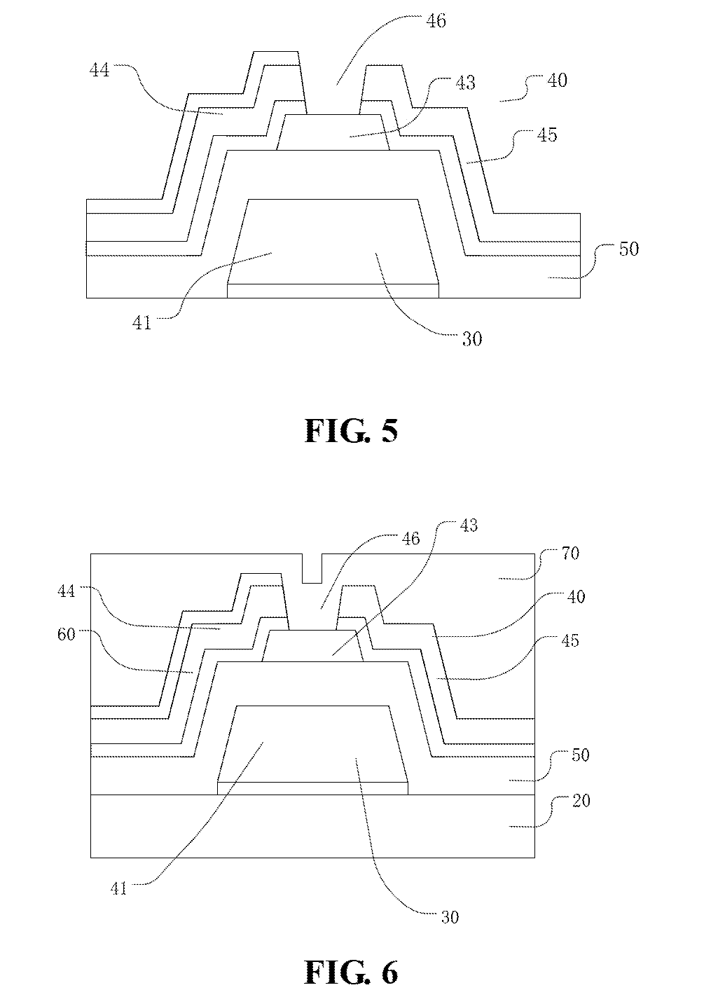

In one or more embodiments, as shown in FIGS. 5, 6 and 8, a display panel in embodiments of FIGS. 5, 6 and 8 including: a substrate 20, an insulation layer 50 disposed on the substrate 20, and second-layer wires 60 disposed on the insulation layer 50, where a lower portion of the second-layer wires 60 includes a first high-adhesion metal layer 61, an upper portion of the second-layer wires 60 includes a second high-adhesion metal layer 62, the middle of the second-layer wires 60 includes a middle conducting layer 63, and the second-layer wires 60 are coupled with a source driver of the display panel.

The second-layer wires 60 include a source wire segment 44 disposed on a TFT 40, a data line wire segment connected to the source wire segment 44 and a drain wire segment 45 of the TFT 40. The second high-adhesion metal layer 62 is only disposed on the source wire segment 44 of the second-layer wires 60.

The source wire segment 44 of the TFT 40 adopts the second-layer wires 60 with a three-layer structure, thereby improving the adhesion property of the source wire segment 44 of the TFT 40. Other second-layer wires 60 adopt wires with a two-layer structure, thereby decreasing the thickness of the display panel.

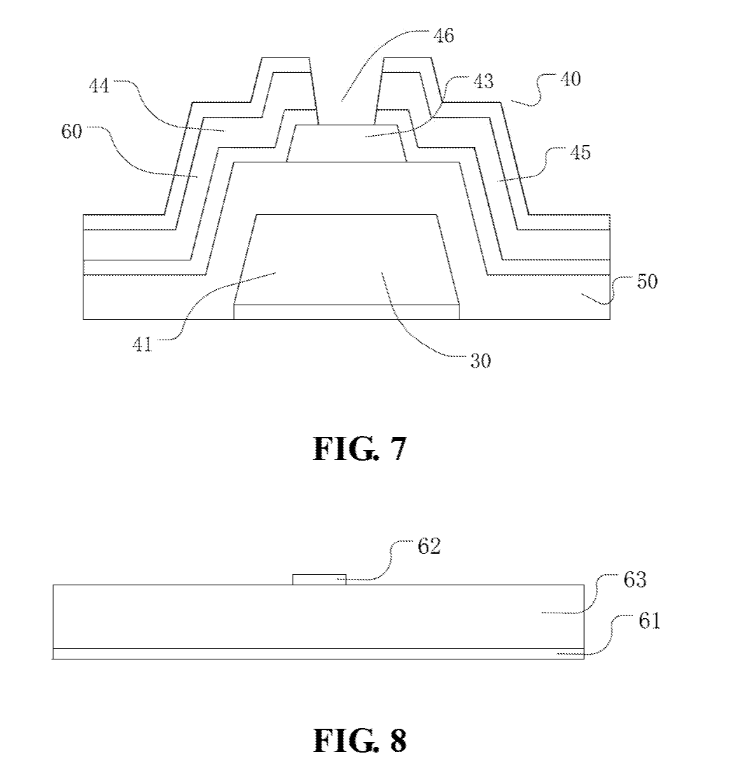

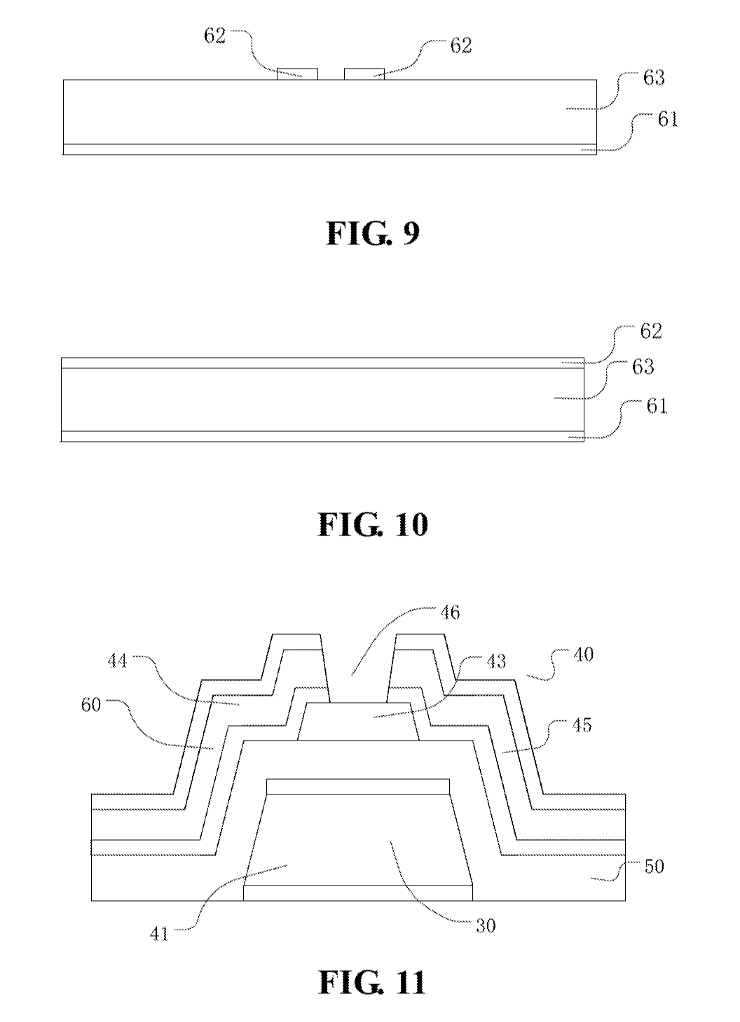

In one or more embodiments, as shown in FIGS. 7 and 9, a display panel in embodiments of FIGS. 7 and 9 including: a substrate 20, an insulation layer 50 disposed on the substrate 20, and second-layer wires 60 disposed on the insulation layer 50, where a lower portion of the second-layer wires 60 includes a first high-adhesion metal layer 61, an upper portion of the second-layer wires 60 includes a second high-adhesion metal layer 62, the middle of the second-layer wires 60 includes a middle conducting layer 63, and the second-layer wires 60 are coupled with a source driver of the display panel.

The second-layer wires 60 include a drain wire segment 45 disposed on a TFT 40, and the second high-adhesion metal layer 62 is disposed on the drain wire segment 45 of the second-layer wires 60.

The drain wire segment 45 of the TFT 40 also adopts the second-layer wires 60 with a three-layer structure, and the drain wire segment 45 may also obtain good adhesiveness. Of course, the second-layer wires 60 also include a source wire segment 44 disposed on the TFT 40, and the second high-adhesion metal layer 62 is disposed on the source wire segment 44 of the second-layer wires 60.

In one or more embodiments, as shown in FIG. 7 and FIG. 10, a display panel in embodiments of FIGS. 7 and 10 including: a substrate 20, an insulation layer 50 disposed on the substrate 20, and second-layer wires 60 disposed on the insulation layer 50, where a lower portion of the second-layer wires 60 includes a first high-adhesion metal layer 61, an upper portion of the second-layer wires 60 includes a second high-adhesion metal layer 62, the middle of the second-layer wires 60 includes a middle conducting layer 63, and the second-layer wires 60 are coupled with a source driver of the display panel. The second-layer wires 60 are integrally covered with the first high-adhesion metal layer 61 and the second high-adhesion metal layer 62.

The second-layer wires 60 adopt three-layer structures. Therefore, the property of the TFT 40 is improved, overall adhesiveness of the display panel is better, quality of the second-layer wires 60 is improved, product yield is enhanced, and production cost is reduced.

As shown in FIGS. 2-3 and FIGS. 11-12, a display panel in embodiments of FIGS. 2-3 and FIGS. 11-12 includes a substrate 20, an insulation layer 50 disposed on the substrate 20, and second-layer wires 60 disposed on the insulation layer 50, where a lower portion of the second-layer wires 60 includes a first high-adhesion metal layer 61, an upper portion of the second-layer wires 60 includes a second high-adhesion metal layer 62, the middle of the second-layer wires 60 includes a middle conducting layer 63, and the second-layer wires 60 are coupled with a source driver of the display panel.

The display panel also includes first-layer wires 30 positioned between the substrate 20 and the insulation layer 50. The first-layer wires 30 are integrally covered with a third high-adhesion metal layer and a fourth high-adhesion metal layer. The first-layer wires 30 include a gate wire segment arranged at the TFT 40. A semiconductor layer 43 corresponding to a gate 41 is disposed on the insulation layer 50. A source wire segment 44 and a drain wire segment 45 of the TFT 40, separated from each other, are disposed on two ends of the semiconductor layer 43. A channel 46 is positioned between the source wire segment 44 and the drain wire segment 45. The semiconductor layer 43 is disposed on a bottom of the channel 46.

The substrate 20 is integrally covered with the first-layer wires 30. Either the gate wire segment of the TFT 40 or a connecting segment between a line scanning driver and the gate 41 of the TFT 40 adopts a three-layer structure. Therefore, the property of the TFT 40 is improved, the overall adhesiveness of the display panel is better, quality of the first-layer wires 30 is improved, product yield is enhanced, and production cost is reduced.

In one or more embodiments, the second-layer wires 60 are integrally covered with the first high-adhesion metal layer 61 and the second high-adhesion metal layer 62.

The second-layer wires 60 adopt three-layer structures. Therefore, the property of the TFT 40 is improved, the overall adhesiveness of the display panel is better, quality of the second-layer wires 60 is improved, product yield is enhanced, and production cost is reduced.

In one or more embodiments, the second high-adhesion metal layer 62 can be only disposed on the source wire segment 44 of the second-layer wires 60, the second high-adhesion metal layer 62 can be only disposed on the drain wire segment 45 of the second-layer wires 60, and the second high-adhesion metal layer 62 can be only disposed on the source wire segment 44 and the drain wire segment 45 of the second-layer wires 60.

The thickness of the middle conducting layer 63 is greater than the thickness of the first high-adhesion metal layer 61 and thickness of the second high-adhesion metal layer 62.

The thickness of the middle conducting layer 63 is greater than the thickness of the first high-adhesion metal layer 61 and is also greater than the thickness of the second high-adhesion metal layer 62. The middle conducting layer 63 may adopt metal with lower resistance property and is thicker so as to effectively decrease the resistance and the parasitic capacitance of the second-layer wires 60 of the panel. The first high-adhesion metal layer 61 and the second high-adhesion metal layer 62 adopt metal with better adhesion property. The middle conducting layer 63 is connected to an upper layer and a lower layer by the first high-adhesion metal layer 61 and the second high-adhesion metal layer 62, so that the adhesiveness is better and the middle conducting layer 63 is difficult to be peeled from the upper layer and the lower layer. The first high-adhesion metal layer 61 and the second high-adhesion metal layer 62 are mainly used for adhering the upper layer and the lower layer, so that the thickness is small and cost can be saved. Optionally, the thickness of the middle conducting layer 63 can be greater than the sum of the thicknesses of the first high-adhesion metal layer 61 and the second high-adhesion metal layer 62.

In one or more embodiments, the width of the bottom of the middle conducting layer 63 is greater than the width of the top of the middle conducting layer 63. The width of the first high-adhesion metal layer 61 is the same as the width of the bottom of the middle conducting layer 63. The width of the second high-adhesion metal layer 62 is the same as the width of the top of the middle conducting layer 63.

The width of the bottom of the middle conducting layer 63 is greater than the width of the top of the middle conducting layer 63, so that manufacturing is convenient, molding is stable, and yield is high. The width of the first high-adhesion metal layer 61 is the same as the width of the bottom of the middle conducting layer 63, and the width of the second high-adhesion metal layer 62 is the same as the width of the top of the middle conducting layer 63, so that manufacturing is convenient. Contact area between the middle conducting layer 63 and the first high-adhesion metal layer 61 and contact area between the middle conducting layer 63 and the second high-adhesion metal layer 62 are larger, so that the adhesion is better. Optionally, the middle conducting layer 63 is a trapezoid, in particular to an isosceles trapezoid.

In one or more embodiments, the middle conducting layer 63 is made of copper, aluminum, silver, gold, chromium, molybdenum or an alloy of the above metal, and the first high-adhesion metal layer 61 and the second high-adhesion metal layer 62 are both made of molybdenum or a molybdenum alloy.

The copper, the aluminum, the silver, the gold, the chromium, the molybdenum or the alloy of the above metal have better conductivity and lower resistance property, so as to meet the need of the display panel. The molybdenum or the molybdenum alloy can realize better adhesiveness. On one hand, the molybdenum or the molybdenum alloy can be better adhered with the metal of the middle conducting layer 63, and on the other hand, the molybdenum or the molybdenum alloy can be better adhered and fixed with other layers of the display panel, such as a filter layer, the insulation layer 50, a passivation layer 70 (a PV layer) and the like, and the molybdenum or the molybdenum alloy is convenient in material selection and mature in a manufacturing technology. Additional raw materials are not needed, so that cost of the raw materials and storage cost are reduced. New materials do not need to be added in a material list, so as to facilitate process management and purchase. The second high-adhesion metal layer 62 may be disposed by a set of devices shared with the first high-adhesion metal layer 61 without additional devices, and subsequent etching does not need additional devices and materials.

The first-layer wires 30 may use a structure of the second-layer wires 60.

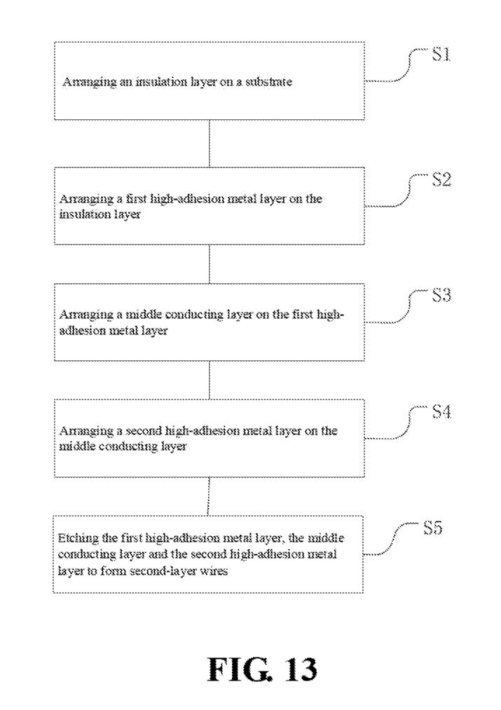

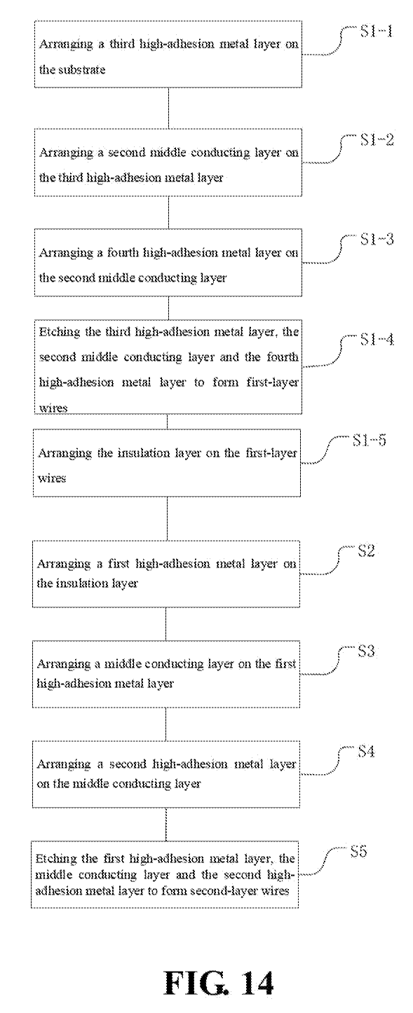

According to another aspect of the present application, as shown in FIGS. 13-14, the present application also discloses a manufacturing process of a display panel, includes the following steps:

S1: disposing an insulation layer on a substrate,

S2: disposing a first high-adhesion metal layer on the insulation layer,

S3: disposing a middle conducting layer on the first high-adhesion metal layer,

S4: disposing a second high-adhesion metal layer on the middle conducting layer, and

S5: etching the first high-adhesion metal layer, the middle conducting layer and the second high-adhesion metal layer to form second-layer wires.

The first high-adhesion metal layer, the middle conducting layer and the second high-adhesion metal layer of the second-layer wires are sequentially disposed on the insulation layer and then are etched together, thereby improving quality of the second-layer wires, enhancing product yield, reducing production cost and enhancing adhesiveness of the second-layer wires with the insulation layer and other layers, so that peeling of the second-layer wires and peeling of other layers connected to the second-layer wires are difficult to be caused, where the first high-adhesion metal layer and the second high-adhesion metal layer adopt identical materials, and additional raw materials are not needed. Therefore, cost of the raw materials and storage cost are reduced. New materials do not need to be added in a material list, so as to facilitate process management and purchase. The second high-adhesion metal layer may be disposed by a set of devices shared with the first high-adhesion metal layer without additional devices, and subsequent etching does not need additional devices and materials.

In one or more embodiments, the step of disposing the insulation layer on the substrate including:

S1-1: disposing a third high-adhesion metal layer on the substrate,

S1-2: disposing a second middle conducting layer on the third high-adhesion metal layer,

S1-3: disposing a fourth high-adhesion metal layer on the second middle conducting layer,

S1-4: etching the third high-adhesion metal layer, the second middle conducting layer and the fourth high-adhesion metal layer to form first-layer wires, and

S1-5: disposing the insulation layer on the first-layer wires.

The third high-adhesion metal layer, the second middle conducting layer and the fourth high-adhesion metal layer of the first-layer wires are sequentially disposed on the substrate and then are etched together, thereby improving quality of the first-layer wires, enhancing product yield, reducing production cost and enhancing adhesiveness of the first-layer wires with the insulation layer and other layers, so that peeling of the first-layer wires and peeling of other layers connected to the first-layer wires are difficult to be caused. Therefore, the overall adhesiveness of the display panel is better.

In one or more embodiments, the first-layer wires are a scanning line of the display panel, and the second-layer wires are a data line of the display panel.

In above embodiments, the material of the substrate may be selected from glass, plastics, and the like.

In above embodiments, the display panel may, for example, include an LCD panel, a plasma panel, an organic light emitting diode (OLED) panel, a quantum dot light emitting diode (QLED) panel and the like. The LCD panel is taken as an example, where the LCD panel includes a TFT substrate and a CF substrate opposite to each other, liquid crystals and photo spacers (PS) are positioned between the TFT substrate and the CF substrate, a TFT is disposed on the TFT substrate, and a color filter layer is disposed on the CF substrate.

In above embodiments, the CF may include the TFT array, a color filter and the TFT array may be formed on a same substrate, and the TFT array basically may include the color filter layer.

In above embodiments, the display panel of the present application may be a curved-surface panel.

The above contents are detailed descriptions of the present application in combination with specific optional embodiments. However, the concrete implementation of the present application shall not be considered to be only limited to these descriptions. For those ordinary skilled in the art to which the present application belongs, several simple deductions or replacements may be made without departing from the conception of the present application, all of which shall be considered to belong to the protection scope of the present application.

What is claimed is:

1. A display panel, comprising:
a substrate;
an insulation layer disposed on the substrate; and
second-layer wires disposed on the insulation layer, wherein a lower portion of the second-layer wires comprises a first high-adhesion metal layer, an upper portion of the second-layer wires comprises a second high-adhesion metal layer, a middle of the second-layer wires comprises a middle conducting layer, and the second-layer wires are coupled with a source driver of the display panel; and
the display panel also comprises first-layer wires positioned between the substrate and the insulation layer, wherein the first-layer wires are integrally covered with a third high-adhesion metal layer and a fourth high-adhesion metal layer, the first-layer wires comprise a gate wire segment disposed on a thin film transistor (TFT), a semiconductor layer corresponding to a gate is disposed on the insulation layer, a source wire segment and a drain wire segment of the TFT, separated from each other, are disposed on two ends of the semiconductor layer, a channel is positioned between the source wire segment and the drain wire segment, the semiconductor layer is disposed on the bottom of the channel and the second-layer wires are integrally covered with the first high-adhesion metal layer and the second high-adhesion metal layer;
wherein the thickness of the middle conducting layer is greater than the thickness of the first high-adhesion metal layer and the thickness of the second high-adhesion metal layer; the width of the bottom of the middle conducting layer is greater than the width of the top of the middle conducting layer; the width of the first high-adhesion metal layer is the same as the width of the bottom of the middle conducting layer; the width of the second high-adhesion metal layer is the same as the width of the top of the middle conducting layer; and the middle conducting layer is made of copper, aluminum, silver, gold, chromium, molybdenum or an alloy of the above metal, and the first high-adhesion metal layer and the second high-adhesion metal layer are both made of molybdenum or a molybdenum alloy.

2. A display panel, comprising:
a substrate;
an insulation layer disposed on the substrate; and
second-layer wires disposed on the insulation layer, wherein a lower portion of the second-layer wires comprises a first high-adhesion metal layer, an upper portion of the second-layer wires comprises a second high-adhesion metal layer, a middle of the second-layer wires comprises a middle conducting layer, and the second-layer wires are coupled with a source driver of the display panel.

3. The display panel according to claim 2, wherein the thickness of the middle conducting layer is greater than the thickness of the first high-adhesion metal layer.

4. The display panel according to claim 2, wherein the thickness of the middle conducting layer is greater than the thickness of the second high-adhesion metal layer.

5. The display panel according to claim 2, wherein the width of the bottom of the middle conducting layer is greater than the width of the top of the middle conducting layer.

6. The display panel according to claim 5, wherein the width of the first high-adhesion metal layer is the same as the width of the bottom of the middle conducting layer.

7. The display panel according to claim 5, wherein the width of the second high-adhesion metal layer is the same as the width of the too of the middle conducting layer.

8. The display panel according to claim 5, wherein the cross section of the middle conducting layer is isosceles trapezoid.

9. The display panel according to claim 2, wherein the middle conducting layer is made of copper, aluminum, silver, gold, chromium, or molybdenum.

10. The display panel according to claim 2, wherein the middle conducting layer is made of metal alloys containing copper, aluminum, silver, gold, chromium or molybdenum.

11. The display panel according to claim 2, wherein the first high-adhesion metal layer and the second high-adhesion metal layer are both made of molybdenum or a molybdenum alloy.

12. The display panel according to claim 2, wherein the second-layer wires comprise a source wire segment disposed on a TFT, and the second high-adhesion metal layer is only disposed on the source wire segment of the second-layer wires.

13. The display panel according to claim 2, wherein the second-layer wires comprise a drain wire segment disposed on the thin film transistor (TFT), and the second high-adhesion metal layer is disposed on the drain wire segment of the second-layer wires.

14. The display panel according to claim 2, wherein the display panel also comprises first-layer wires positioned between the substrate and the insulation layer.

15. The display panel according to claim 13, wherein the first-layer wires are integrally covered with a third high-adhesion metal layer and a fourth high-adhesion metal layer, wherein the first-layer wires comprise a gate wire segment arranged at the thin film transistor (TFT), and a semiconductor layer corresponding to a gate is disposed on the insulation layer, the source wire segment and the drain wire segment of the TFT, separated from each other, are disposed on two ends of the semiconductor layer, a channel is positioned between the source wire segment and the drain wire segment, and the semiconductor layer is disposed on the bottom of the channel.

16. The display panel according to claim 15, wherein the second-layer wires are integrally covered with the first high-adhesion metal layer and the second high-adhesion metal layer.

17. A manufacturing process of a display panel, comprising the following steps:
disposing an insulation layer on a substrate;
disposing a first high-adhesion metal layer on the insulation layer;
disposing a middle conducting layer on the first high-adhesion metal layer;
disposing a second high-adhesion metal layer on the middle conducting layer; and
etching the first high-adhesion metal layer, the middle conducting layer and the second high-adhesion metal layer to form second-layer wires.

18. The manufacturing process of the display panel according to claim 17, wherein the step of disposing the insulation layer on the substrate comprises the following steps:
disposing a third high-adhesion metal layer on the substrate;
disposing a second middle conducting layer on the third high-adhesion metal layer;
disposing a fourth high-adhesion metal layer on the second middle conducting layer;
etching the third high-adhesion metal layer, the second middle conducting layer and the fourth high-adhesion metal layer to form first-layer wires; and
disposing the insulation layer on the first-layer wires.
